(19) United States
(12) Patent Application Publication
(10) Pub. No.: US 2024/0318350 A1
(43) Pub. Date: Sep. 26, 2024

(54) DEFECT REDUCTION IN DIAMOND

(71) Applicant: M7D Corporation, Beltsville, MD (US)

(72) Inventors: John P. Ciraldo, Clarksburg, MD (US); Joshua Blackketter, Laurel, MD (US); Jonathan Levine-Miles, Silver Spring, MD (US)

(21) Appl. No.: 18/229,053

(22) Filed: Aug. 1, 2023

Related U.S. Application Data
(60) Provisional application No. 63/453,401, filed on Mar. 20, 2023.

(51) Int. Cl. C30B 25/04; C30B 25/16; C30B 29/04; C30B 33/08

(52) U.S. Cl. CPC C30B 25/04; C30B 25/16; C30B 29/04; C30B 33/08

(57) ABSTRACT

A method grows diamond by providing an initial substrate having a growth surface. A first layer of diamond growth inhibitor is positioned over a first area of the growth surface. Diamond is grown on the growth surface using chemical vapor deposition. Growing the diamond includes growing a first lateral overgrowth region over the diamond growth inhibitor. After growing the first lateral overgrowth region, a second layer of diamond growth inhibitor is positioned over a second area of the growth surface that is at least partially offset from the first area.

### PRIORITY

This patent application claims priority from provisional U.S. patent application No. 63/453,401, filed Mar. 20, 2023, entitled, “DEFECT REDUCTION IN DIAMOND,” the disclosure of which is incorporated herein, in its entirety, by reference.

### GOVERNMENT RIGHTS

This invention was made with government support under HR0011-23-9-0105 awarded by DARPA. The government has certain rights in the invention.

### FIELD OF THE INVENTION

Illustrative embodiments of the invention generally relate to growing diamond and, more particularly, illustrative embodiments relate to removing defects from grown diamond.

### BACKGROUND OF THE INVENTION

Imperfections in the crystal lattice of diamond are common. Such defects may be the result of lattice irregularities or extrinsic substitutional or interstitial impurities, introduced during or after the diamond growth. The defects affect the material properties of diamond and determine to which type a diamond is assigned; the most dramatic effects are on the diamond color and electrical conductivity, as explained by the electronic band structure.

The defects can be detected by different types of spectroscopy, including electron paramagnetic resonance (EPR), x-ray diffraction, Raman spectroscopy, luminescence induced by light (photoluminescence, PL) or electron beam (cathodoluminescence, CL), and absorption of light in the infrared (IR), visible and UV parts of the spectrum. The absorption spectrum is used not only to identify the defects, but also to estimate their concentration; it can also distinguish natural from synthetic or enhanced diamonds.

### SUMMARY OF VARIOUS EMBODIMENTS

In accordance with one embodiment of the invention, a method grows diamond by providing an initial substrate having a growth surface. A first layer of diamond growth inhibitor is positioned over a first area of the growth surface. Diamond is grown on the growth surface using chemical vapor deposition. Growing the diamond includes growing a first lateral overgrowth region over the diamond growth inhibitor. After growing the first lateral overgrowth region, a second layer of diamond growth inhibitor is positioned over a second area of the growth surface that is at least partially offset from the first area.

In various embodiments, the second layer of diamond growth inhibitor is positioned at a height that is equal to or greater than the first lateral overgrowth region. The first layer of diamond growth inhibitor and the second layer of diamond growth inhibitor may be formed from the same material.

The steps of positioning diamond growth inhibitor over an offset area of the growth surface and growing diamond on the growth surface using chemical vapor deposition may be repeated until threading defect density is reduced by at least 50% relative to the initial substrate in a reduced defect area. The reduced defect area may have a maximum dimension of at least 2 inches.

In various embodiments, diamond is grown on the growth surface using chemical vapor deposition, and the grown diamond may include a second lateral overgrowth region over the diamond growth inhibitor. The lateral overgrowth region and the second lateral overgrowth region may be on different layers.

A third diamond growth inhibitor may be positioned over a third area of the growth surface that is at least partially offset from the first area and the second area. Diamond may be grown on the growth surface using chemical vapor deposition, and the grown diamond may include a third lateral overgrowth region over the diamond growth inhibitor. In various embodiments, the first area of the growth surface, the second area of the growth surface, and the third area of the growth surface may not overlap.

The method may repeat the steps of: positioning diamond growth inhibitor over an area of the growth surface, and growing diamond on the growth surface using chemical vapor deposition, such that the grown diamond includes an additional overgrowth region over the diamond growth inhibitor, until substantially all of the growth surface of the diamond is defect free and/or high-quality.

Some embodiments may be used to grow a large-area high-quality grown diamond region. The large-area high-quality grown diamond region may be removed from the remainder of the grown diamond. The substrate may be a single-crystal diamond substrate. Alternatively, the substrate may be formed from a non-diamond material. The diamond may be grown heteroepitaxially. The grown diamond may be single crystal.

In various embodiments, non-diamond deposits over the diamond growth inhibitor. The non-diamond may be a form of carbon, such as amorphous carbon. In various embodiments, the diamond growth inhibitor may be formed from gold. Additionally, or alternatively, the diamond growth inhibitor may be formed from aluminum oxide.

Some embodiments may etch the growth surface to form etched regions. The diamond growth inhibitor may function as a mask that prevents or reduces the formation of etched regions beneath the diamond growth inhibitor. The method may deposit a first doped diamond portion using chemical vapor deposition. The diamond growth inhibitor may be removed. The diamond growth inhibitor may be positioned over a second area of the growth surface. The growth surface may be etched to form second etched regions. The diamond growth inhibitor may function as a mask that prevents or reduces the formation of the second etched regions beneath the diamond growth inhibitor. The method may deposit a second doped diamond portion using chemical vapor deposition. The second doped diamond portion may have a different doping concentration from the first doped diamond portion.

In some embodiments, the doped diamond portion includes boron, nitrogen, silicon, and/or phosphorous as dopants. Some embodiments may include an adherence portion between the diamond growth inhibitor and the diamond growth surface.

Some embodiments include a diamond grown using any of the aforementioned methods.

In accordance with another embodiment, a diamond includes a reduced-defect region grown above a higher defect single-crystal diamond region. A non-diamond substrate having a top surface area. The reduced-defect single-crystal diamond region may have an area that is at least 50% of the top surface area of the non-diamond substrate.

In some embodiments, the reduced-defect single-crystal diamond region has an area that is at least 90% of the top surface area of the non-diamond substrate. In some embodiments, the reduced-defect single-crystal diamond region is a sum of a plurality of disjointed regions. Alternatively, in some embodiments, the reduced-defect single-crystal diamond region may be a single continuous region. The reduced-defect single-crystal diamond region may take a variety of shapes, including but not limited to a rectangular shape.

In accordance with another embodiment, a system includes a reduced-defect single-crystal diamond region, a diamond growth inhibitor, and a growth substrate.

Among other things, the growth substrate may be a non-diamond substrate. The growth substrate may be a polycrystalline diamond substrate. The system may include a lateral overgrowth diamond region over the diamond growth inhibitor. Among other shapes, the diamond growth inhibitor may be in the shape of a bar, a hexagon, a circle, a pentagon, or a rectangle.

In some embodiments, the diamond growth inhibitor may cover at least 50% of the growth surface. The diamond growth inhibitor may include a micro-pattern diamond growth inhibitor. The micro-pattern DGI may include an array of micro-pores. The micro-pores may have a given shape. The shape may be rectangular or hexagonal. The micro-pores may be configured to be aligned with the crystal lattice orientation.

The diamond growth inhibitor may be configured to prevent or inhibit formation of single-crystal and polycrystalline diamond at a surface of the DGI when depositing diamond using a chemical vapor deposition growth process. Accordingly, diamond bonds may be unmeasurable by X-ray diffraction.

In various embodiments, the diamond growth inhibitor may be configured to cause formation of non-diamond carbon as diamond is deposited in a CVD diamond growth process thereon, when depositing diamond using a chemical vapor deposition growth process.

Removing the DGI may form a void in the diamond. The DGI may cover at least about 90% and less than 100% of the substrate surface. The DGI may have a pore size. The pore size may be less than 500 microns, less than 50 microns, and/or less than 5 microns. In some embodiments, the pore size may be greater than 1 nm.

In various embodiments, defect density is reduced uniformly across the reduced defect area. The substrate surface may have a maximum dimension that is at least 40 mm. In some embodiments, the substrate surface has a maximum dimension that is at least 20 mm.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows a substrate in accordance with illustrative embodiments.

FIG. 1B schematically shows the diamond substrate of FIG. 1A with diamond grown thereon in accordance with illustrative embodiments.

FIG. 2 shows a process for growing large regions of reduced-defect diamond in accordance with illustrative embodiments.

FIGS. 3A-3E schematically show side and top views of a process of using epitaxial lateral overgrowth to reduce defects in a grown diamond in accordance with illustrative embodiments.

FIG. 3F schematically shows details of the diamond growth inhibitor of FIG. 3E.

FIGS. 4A-4B schematically show alternative arrangements of diamond growth inhibitor in accordance with illustrative embodiments.

FIG. 5 schematically shows another alternative arrangement for a layer of diamond growth inhibitor in accordance with illustrative embodiments.

FIG. 6 is a polarized top view image of a reduced-defect/no-defect lateral overgrowth region in accordance with illustrative embodiments.

### DESCRIPTION OF ILLUSTRATIVE EMBODIMENTS

Illustrative embodiments include a process of using selective deposition and lateral overgrowth to produce high quality diamond by removing defects in epitaxially grown diamond. Diamond growth inhibitor (“DGI”, e.g., gold) patterns are selectively deposited on diamond material (e.g., using the selective deposition methods described in U.S. Patent Application No. 63/453,378, which is incorporated herein by reference in its entirety). However, in this case, the diamond is allowed to grow out over the areas where the DGI is positioned, using a lateral growth technique. Growth over areas where DGI is deposited is unconstrained by the substrate below and diamond can be grown with very low defects. This process can then be repeated, plating gold on areas of high defects as many times as desired to produce a single crystal surface demonstrating low defects across the entire region, or across a desired region (e.g., where devices are fabricated on the surface).

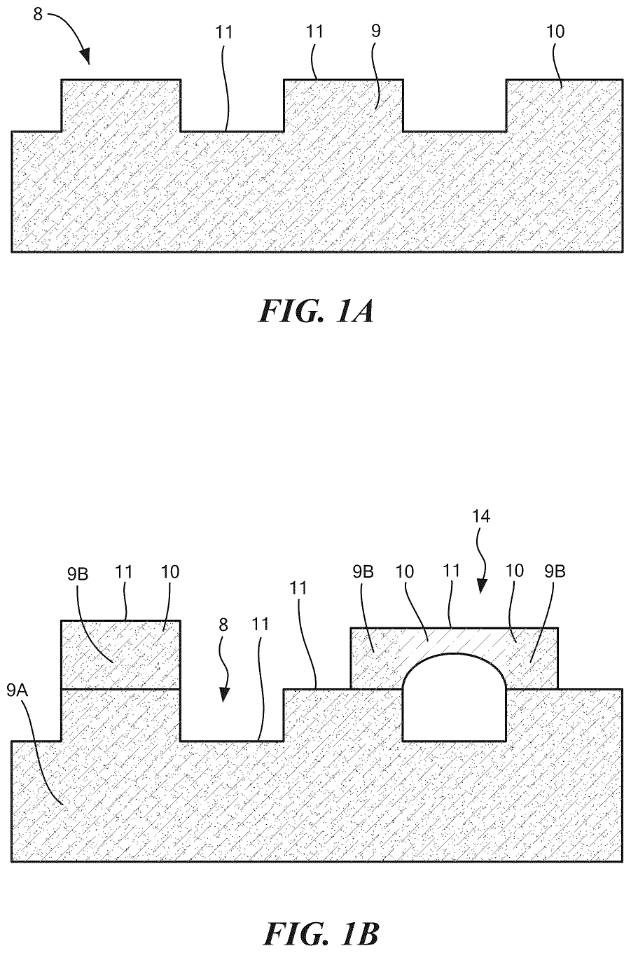

FIG. 1A schematically shows a substrate 8 (e.g., formed from diamond 10 in accordance with illustrative embodiments. Like many substrates 8, the substrate 8 material is rich in defects 9 (represented by little red dots, such as point defect, dislocations, interstitial, lattice strain defects). The substrate has a growth surface 11, on which diamond growth may occur in a CVD process. The growth surface 11 is the growth-facing surface (e.g., top-most surface) of the substrate, on which CVD diamond growth occurs. Thus, the growth surface 11 changes as the diamond 11 grows. As shown, the growth surface 11 does not have to be planar (e.g., the surface 11 may have peaks and valleys).

As shown in FIG. 1A, the growth surface 11 may have protruding and/or receding portions. Furthermore, the growth surface 11 may continue to grow disproportionately. For example, some portions of the growth surface 11 may be covered by diamond growth inhibitor 20, such that the growth surface 11 does not grow diamond directly on the diamond growth inhibitor 20, but diamond does grow over portions not covered by diamond growth inhibitor 20. Thus, it should be understood that diamond does not need to grow over the entirety of the growth surface 11, but merely that diamond would grow on the growth surface 11 in a CVD diamond growth process (e.g., when uncovered and exposed to plasma). As an example, in FIG. 1B, the top surface of the lateral overgrowth portion 14 may form part of the growth surface 11, as the open area beneath the overgrowth portion 14 is no longer exposed to the plasma and does not form the growth surface 11.

Single crystal diamond 10 demonstrates a number of properties that are greatly advantageous for electronics and other applications. However, size limitations, quality, and availability make it difficult to fully utilize diamond 10 for some applications, particularly in the realm of electronics and quantum uses. Illustrative embodiments use a CVD approach to grow diamond 10. Moreover, by use of heteroepitaxy, CVD diamond 10 may be produced in larger sizes than is commonly available. Up to 4-inch wafers have been produced using this method. Unfortunately, CVD diamond 10 tends to be high in crystal defects 9 and it often is not of sufficiently high quality for some applications where the material would be useful. When heteroepitaxy is utilized, achieving sufficient quality may be even more challenging than through homoepitaxy.

FIG. 1B schematically shows the substrate 8 (e.g., diamond substrate) of FIG. 1A with diamond 10 grown thereon in accordance with illustrative embodiments. When diamond 10 is grown on the substrate 8, the defects 9A from the substrate 8 propagate upwards. Therefore, portions of the newly grown diamond 10 include propagated defects 9B. Illustrative embodiments use epitaxial lateral overgrowth 14 methods to reduce propagated defects 9B. As shown, epitaxial lateral overgrowth 14 forms a bridge where the grown diamond 10 material come together. Although the lateral overgrowth 14 is schematically shown as having an arch shape, one skilled in the art will understand that it can take on a variety of shapes (e.g., triangular overgrowth region 14). Thus, the arch shape is shown merely for discussion purposes. The areas of the diamond 10 that are grown directly above the diamond 10 propagate defects 9, but the lateral overgrowth 14 portion does not propagate defects 9B because it is not constrained by the lattice below it. This lateral overgrowth 14 portion of the diamond 10 becomes very low in defects 9 (i.e., forms a reduced defect diamond portion 10).

Epitaxial lateral overgrowth has been used for single-crystal diamond, but is cumbersome, expensive, and produces challenges for large-scale manufacturing. Furthermore, epitaxial lateral overgrowth generally requires etching. Various embodiments can provide epitaxial lateral overgrowth 14 without requiring etching, which is a significant advantage.

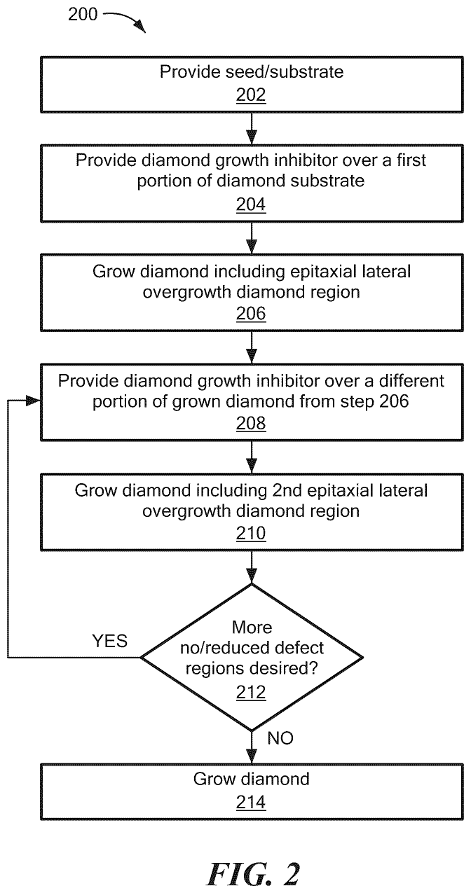

FIG. 2 shows a process for growing large regions of reduced-defect diamond 10 in accordance with illustrative embodiments. It should be noted that this method is substantially simplified from a longer process that may normally be used. Accordingly, the method shown in FIG. 2 may have many other steps that those skilled in the art likely would use. In addition, some of the steps may be performed in a different order than that shown, or at the same time. Furthermore, some of these steps may be optional in some embodiments. Accordingly, the process 200 is merely exemplary of one process in accordance with illustrative embodiments of the invention. Those skilled in the art therefore can modify the process as appropriate.

A problem solved by the process described above is the growth of large high-quality diamond 10. It is difficult to grow large high-quality diamond 10 using CVD. Generally, this requires growing diamond 10 on large substrates 8 using heteroepitaxy. But heteroepitaxial processes generally lead to low quality diamond 10. Alternatively, CVD diamond 10 can be homoepitaxially grown on a diamond substrate 8, which is limited by the size of the diamond substrate 8 that the process begins with. It is difficult to obtain high quality large diamond 10 substrates 8. Therefore, the size of a high-quality grown diamond 10 is generally constrained by the size of the high-quality diamond 10 substrate 8 available.

On the other hand, the problem with large non-diamond substrates 8 is that the quality is very poor because of lattice mismatch. The crystal structure of the non-diamond substrate is different (only by a few %, or it would not be possible to grow sp3 diamond on it at all), and those differences add up over distance, leading to increasing stress and subsequent dislocations or cracking—and the grown diamond 10 is highly defective. The process described below helps with reducing/removing defects 9. The process may be used to heteroepitaxially or homoepitaxially grow high quality diamond 10.

The process begins at step 202 by providing the substrate 8. In some embodiments, the process may be a homoepitaxial process, and thus the substrate 8 may be diamond 10, such as single-crystal or polycrystalline diamond 10. In some embodiments, the process may be a heteroepitaxial process, and therefore, the substrate 8 may be formed from some other suitable material (e.g., iridium film on sapphire, silicon, and/or MgO (for single crystal), e.g., 2″, 4″ diameter, square/rectangular, circular).

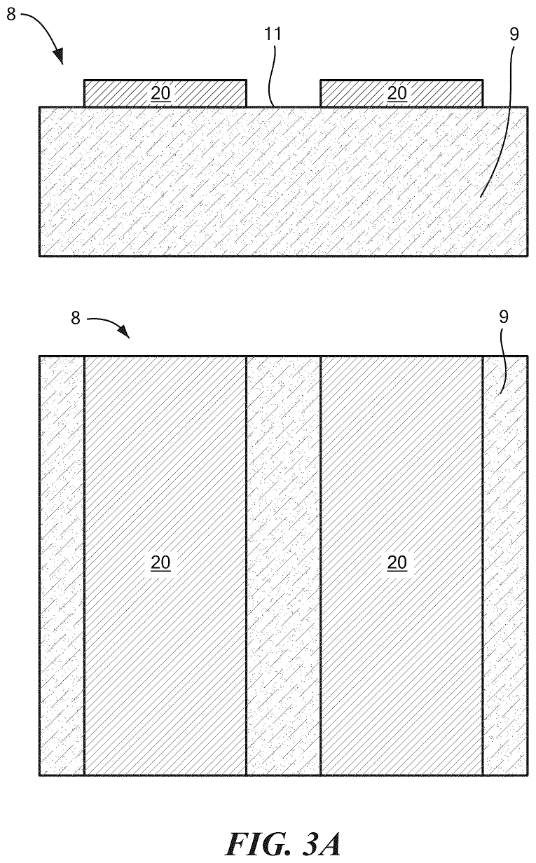

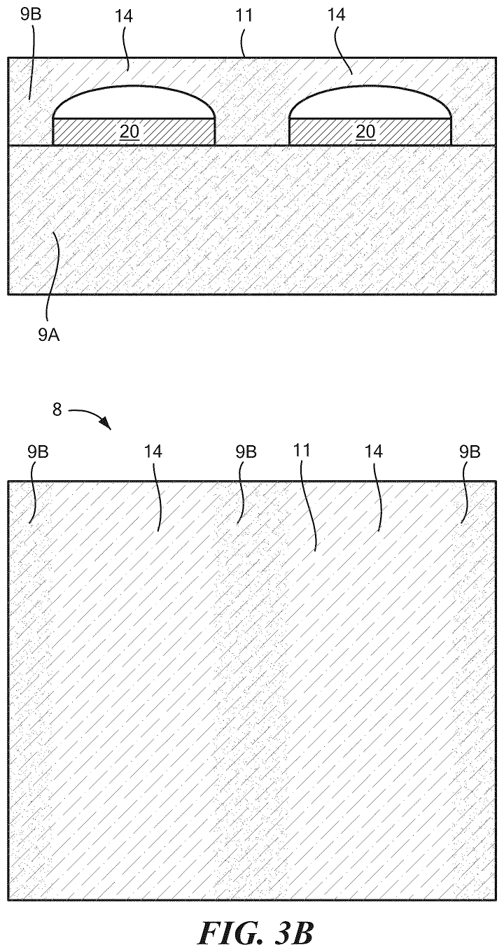

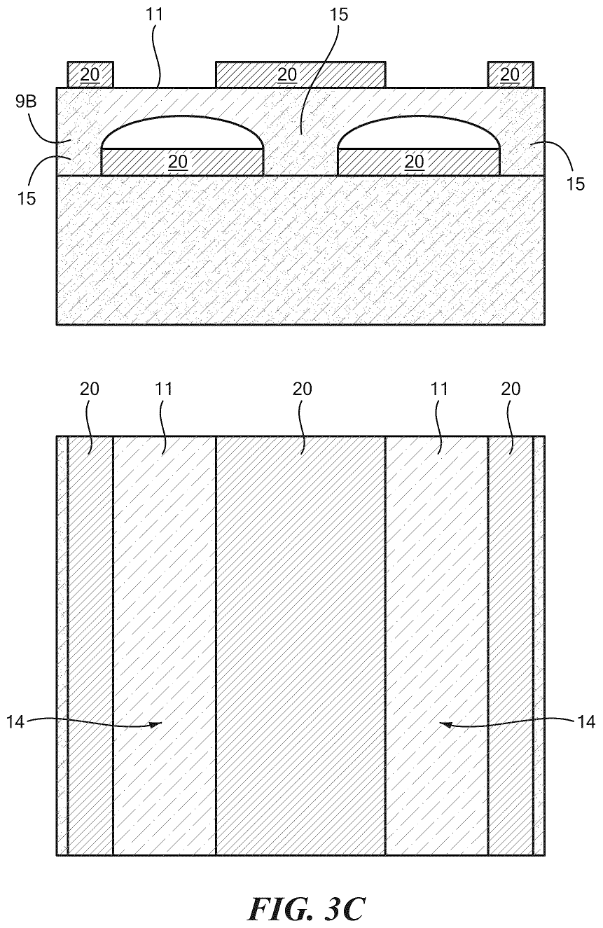

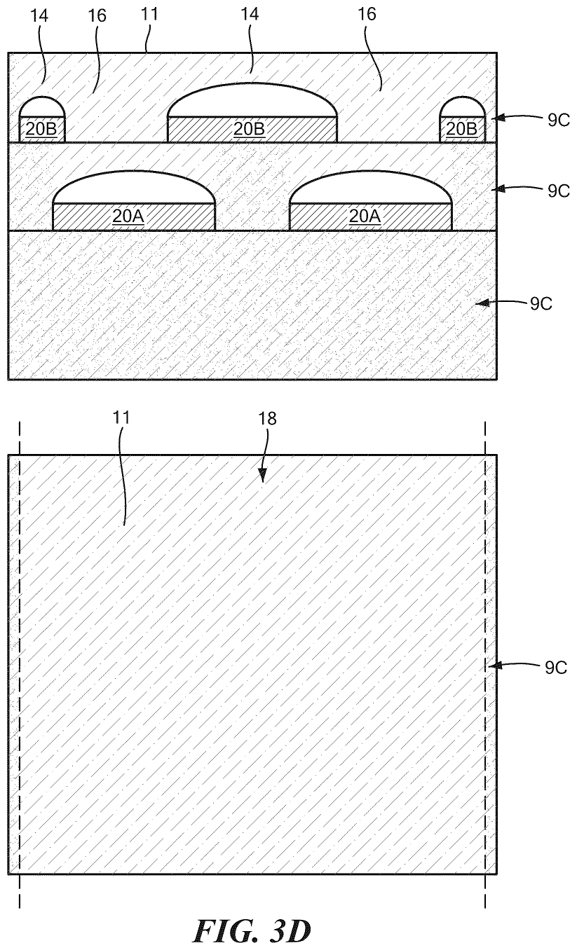

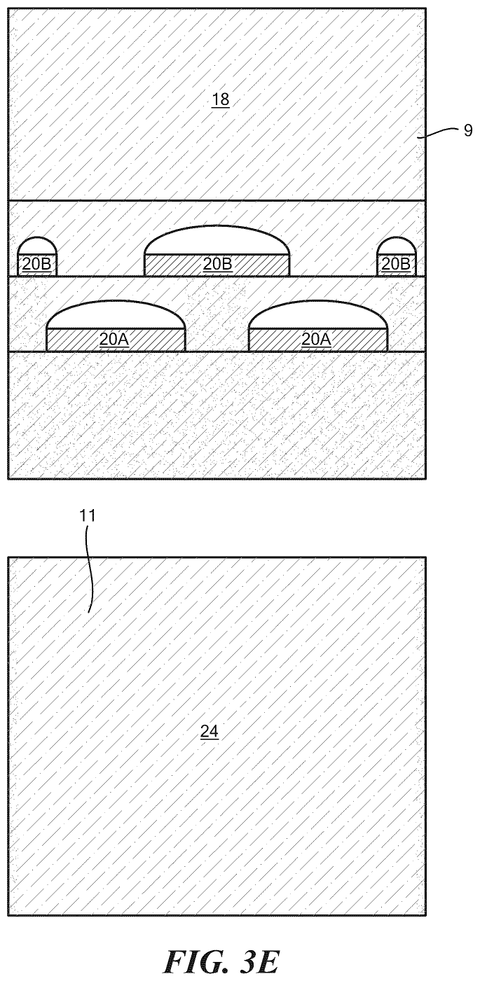

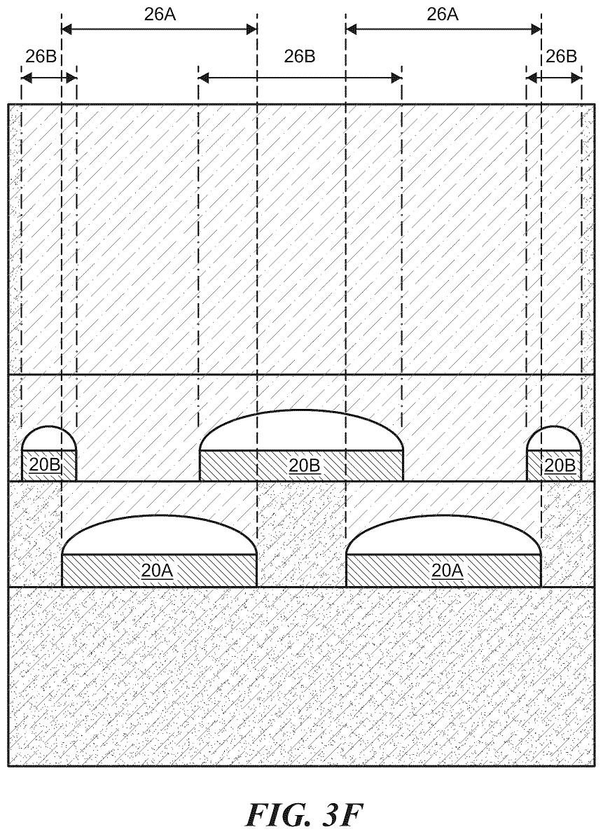

At step 204, the process positions diamond growth inhibitor 20 over a first portion of the diamond substrate 8. FIG. 3A schematically shows a side view and a top view of diamond growth inhibitor 20 positioned over a first portion of the diamond substrate 8 in accordance with illustrative embodiments. The defects 9 are represented as red dots, but it should be understood that the number and/or location of defects 9 are not limited herein. The red dot representation is merely shown for discussion purposes.

Furthermore, for the sake of discussion, FIG. 3A shows two diamond growth inhibitors 20 of roughly equal size. It should be understood that various embodiments may include one or more diamond growth inhibitor 20 on a given layer. Furthermore, the diamond growth inhibitor 20 is not limited to the shape or size shown in the figures. Those skilled in the art will understand that illustrative embodiments are intended to cover a wide variety of quantities, shapes, sizes, patterns, and/or positions for the diamond growth inhibitor 20.

In various embodiments, certain materials function as diamond growth inhibitor 20 when epitaxially growing diamond 10 using CVD. The diamond growth inhibitor 20 (“DGI 20”) offers a surface that prevents single crystal or polycrystalline diamond 10 growth under CVD growth conditions. In various embodiments, diamond 10 growth is inhibited such that no more than a negligible amount of diamond bonds to the DGI, such that diamond bonds are not detectable using X-ray diffraction.

Instead, the deposited carbon forms an amorphous carbon deposit on the DGI 20 (instead of diamond 10), which is relatively easily removed (e.g., blown away) and/or wiped away. In particular, gold 20 and/or aluminum oxide may be used as diamond growth inhibitor 20. Accordingly, diamond growth inhibitor 20 may be placed over portions of the growth surface 11 to selectively prevent diamond 10 growth.

Because gold 20 has preferable properties as a diamond growth inhibitor 20, it will be referred to throughout various embodiments. However, illustrative embodiments may include the use of aluminum oxide, or any other diamond growth inhibitor 20, in addition to or instead of gold 20. For the sake of discussion, various embodiments may refer to gold 20 and DGI 20 interchangeably. However, it should be understood that any reference to gold 20 is intended to apply to DGI 20 generally, and is not limited to DGI 20 formed from gold.

It can be challenging to deposit gold 20 directly on carbon or other substrates 8. Thus, various embodiments may include a small layer of adherence material/an adhesion layer (e.g., angstrom-nanometer scale of chrome, molybdenum, and/or titanium) between the gold 20 and the substrate 8 (not shown). Various embodiments may include an adherence layer of between about 10 nanometers and about 20 nanometers in thickness. Some embodiments may include an adherence material that is up to 1 micron in thickness. As used herein, DGI 20 is considered to be deposited on or over the substrate 8 even when an adherence material is added therebetween.

The process proceeds to step 206, which epitaxially grows diamond 10 in a CVD chamber. FIG. 3B schematically shows a side view and a top view of growing diamond 10 over the substrate 8 of FIG. 3A. As shown, diamond 10 growth directly over the gold 20 is suppressed. The gold 20 suppresses direct diamond 10 growth thereon and allows for low/no-defect lateral overgrowth 14 regions. As shown, the laterally grown diamond region 14 has reduced defects 9 or is substantially defect-free (represented by the lack of red dots). In contrast, the region grown directly above the substrate 8 tends to propagate defects 9B from the defects 9A of the layer beneath (e.g., the substrate 8).

At step 208, the process positions diamond growth inhibitor 20 over a different portion of the grown diamond 10 from step 206. FIG. 3C schematically shows a side view and a top view of positioning diamond growth inhibitor 20 over a different portion of the diamond 10. As shown, second gold 20 bars are positioned to cover at least a portion of the directly grown diamond having the propagated defects 9B.

At step 210, diamond 10 is grown in the CVD chamber such that a second epitaxial lateral overgrowth 14 diamond region is grown. FIG. 3D schematically shows a side view and a top view of epitaxially growing diamond 10 over the growth surface 11 of FIG. 3C. As shown in FIG. 3D, the substrate 8 can be said to have two layers of DGI 20 (e.g., a first layer of DGI 20A and a second layer of DGI 20B).

As in FIG. 3B, defect-free/reduced defect laterally grown regions 14 are grown over the gold 20. Additionally, the regions 16 grown directly over the previous reduced defect laterally grown regions 14 also have reduced defects 9 because they are grown over a high quality diamond 10. Accordingly, a large defect-free/reduced defect region 18 is grown, formed by the reduced defect upwardly grown regions 16 and the reduced defect laterally grown regions 14. As shown, for example, some defects 9C may be propagated upwardly from defects 9B in the lower region.

The process then proceeds to step 212, which asks whether there are more no defect/reduced defect regions to be grown. If yes, then process returns to step 208, and more diamond growth inhibitor 20 may be provided over a different portion of the diamond 10. This process may be repeated multiple times until a high-quality diamond 10 of desirable size is grown. Thus, illustrative embodiments may use one, two, three, or more layers of DGI 20 to achieve a desirable reduction in defects 9 and to produce a large reduced-defect region 18. After the high-defect regions in the diamond 10 have been reduced, the process proceeds to step 214, which grows high-quality diamond 10 over the large defect-free/reduced defect grown region 18.

FIG. 3E schematically shows a top view and a side view of diamond 10 grown directly over the large area high-quality diamond region 18. The diamond may then be polished, and optionally cut away from the embedded gold 20. The process then comes to an end.

Although not mentioned previously, in some embodiments, the growth may be interrupted after sufficient growth time (e.g. sufficient time to deposit several hundred nanometers of diamond 10) and the metal films may be removed either by a wet etch technique, or using dry etch-the latter may be done in-situ in the CVD chamber. Diamond 10 growth may then resume, at least until such time that lateral overgrowth 14 occurs and overtakes the ridges or pits remaining from where gold 20 had been deposited. Again, this process may be repeated to further reduce the density of crystalline defects 9 and stress along the crystal surface.

It should be reiterated various embodiments may achieve the same or similar outcomes to the process described above. For example, various embodiments may have 50% of the growth surface 11 covered with gold 20 on a given layer, 60% of the growth surface 11 covered with the gold 20 on a given layer, etc. It should further be understood that direct growth over gold 20 is suppressed, but lateral overgrowth 14 occurs. Thus, the gold 20 areas on a lower layer become high quality diamond 10 areas in a subsequent layer. The process may be repeated until the entire top layer, or substantially all of the top layer becomes high quality diamond 10 (e.g., high-quality single-crystal diamond 10).

FIG. 3F schematically shows details of the diamond growth inhibitor 20 of FIG. 3E in accordance with illustrative embodiments. As discussed, FIG. 3E describes applying two layers of DGI 20 (i.e., a first layer of DGI 20A and a second layer of DGI 20B). It should be understood that various embodiments may use more than two layers of DGI 20, for example, three layers, four layers, five layers, or more. However, advantageously, having at least two layers of DGI 20 provides a large reduced-defect region 18. The two layers of DGI 20A and 20B provide sufficient support 15 for lateral overgrowth regions 14, while simultaneously being sufficiently offset to provide for large drops in defects (e.g., reducing threading defect density relative to the initial substrate 8 by at least 50%, by at least 60%, by at least 70%, by at least 80%, by at least 90%, and/or by at least 99%) in a large reduced defect region 18 (e.g., having a minimum dimension (e.g., width or diameter) of at least 1″, of at least 2″, of at least 3″, of at least 4″, and/or a maximum dimension (e.g., width or diameter) of up to 5″, of up to 10″, of up to 20″). Additionally, or alternatively, the reduced defect region 18 may be a region of high color (e.g., approaching colorless on the GIA diamond scale), and/or a reduced stress region, relative to corresponding lateral overgrowth support 15 regions (i.e., supports 15 that are not themselves grown over a reduced defect lateral overgrowth 14 portion).

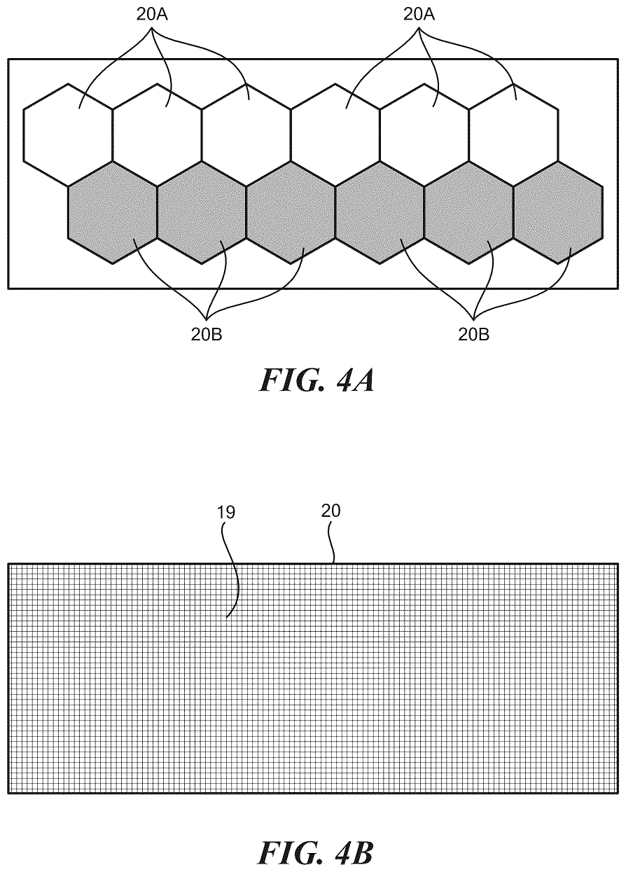

In the CVD process, diamond 10 can be said to be grown vertically. Illustrative embodiments achieve large drops in defect density by providing the first layer of DGI 20A over a first area 26A, and by providing a second layer of DGI 20B over a second area 26B that is at least partially offset horizontally from the first area 26A. As shown in FIG. 3F, there may be some overlap between the areas 26A and 26B, but there is offset, such that one area 26A covers a portion not covered by the second area 26B, and/or vice-versa. This arrangement advantageously reduces and/or prevents the propagation of defects 9 from lower layers. However, not all embodiments require a plurality of layers. As shown and described below (e.g., with reference to FIG. 4B), some embodiments may have a micropore arrangement, either as a single DGI layer 20 or as part of multiple DGI layers 20. For example, some embodiments may include two or more layers of micropore DGIs 20. Additionally, or alternatively, some embodiments may include a plurality of DGI 20 layers (e.g., two, three, four, five, or more layers of DGI 20). Additionally, although illustrative embodiments show a layer of DGI 20 as having a plurality of DGI 20 bars and/or strips, in various embodiments, a DGI 20 layer may include a single DGI 20 (e.g., a single gold bar, a single gold hexagon, a single gold sheet having micropores). FIG. 4A schematically shows an alternative arrangement of DGI 20 in accordance with illustrative embodiments. In FIG. 4, the DGI 20 is formed in the shape of hexagons. FIG. 4A shows the DGI 20 exposed (i.e., without the diamond 10 blocking the top view). Thus, the position of the first layer of DGI 20A and the position of the 2nd layer of DGI 20B may be visualized simultaneously.

FIG. 4B schematically shows an alternative arrangement of DGI 20 in accordance with illustrative embodiments. FIG. 4B shows a top view of a DGI 20 on the substrate 8. FIG. 4B shows the DGI 20 having a plurality of micropores 19. The diamond 10 grows through the micropores and forms micro lateral overgrowth regions 14.

When considering stress/strain, in a well ordered crystal, all of the atoms are evenly spaced. In a poorly ordered crystal/stressed crystal, the atoms are not evenly spaced. The ELO area allows for better order of the atoms, and therefore, reduces the overall stress. Accordingly, illustrative embodiments allow for the formation of reduced stress diamond 10.

Various embodiments refer to defect 9 reduction, but those skilled in the art will understand that various embodiments may improve strain/stress in grown diamond 10. Reduced stress can provide useful applications in optics (e.g., as a diffraction crystal) and electrical applications.

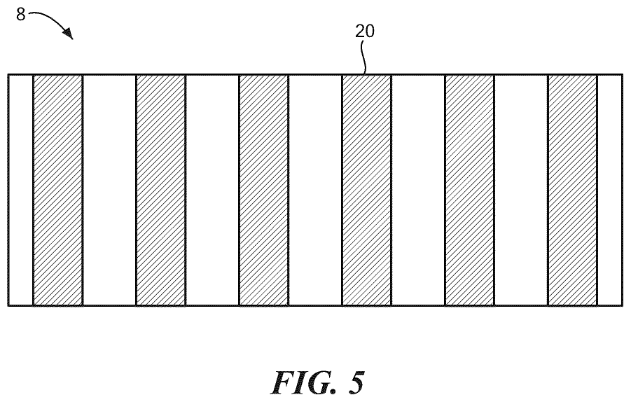

FIG. 5 schematically shows another alternative arrangement for a layer of DGI 20 in accordance with illustrative embodiments. As shown, the DGI 20 may be shaped as bars that extend from edge-to-edge of the substrate 8.

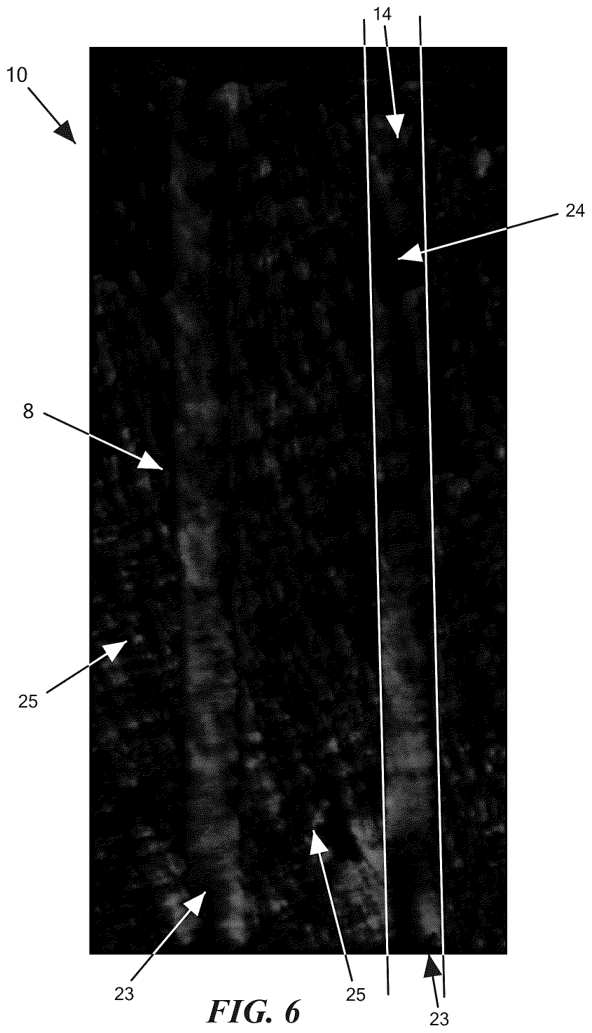

FIG. 6 schematically shows a top view polarized image of a polished diamond substrate 8. The image is provided to show that the lateral overgrowth 14 method described above has been tested and found to include reduced defect regions 23 in the diamond 10. For clarity, FIG. 6 shows a single smooth top surface that is polished. However, in the polarized image, the dark regions represent very low-stress/low-defect regions 14. Noisy/grainy regions 25 represent higher-stress/higher-defect regions. As known to those skilled in the art, polarized images provide a method for examining stress in transparent materials, such as diamond 10.

As shown in FIG. 6, the region 23 within the white lines has large dark areas 24, representing high-quality regions (i.e. having low stress and reduced defects 9). A second reduced defect region 23 is shown in the image. The low-defect regions are regions of lateral overgrowth 14 grown over the gold DGI 20.

It should be understood that various embodiments may use a homo-epitaxial process or hetero-epitaxial process. Semiconductor devices (e.g., transistors) may be grown using the methods described herein, and defects 9 may advantageously be reduced in the regions where semiconductor devices are grown using the methods described herein.

Furthermore, some embodiments may use multiple substrates 8 placed in contact or spaced apart (e.g., a mosaic approach). In some embodiments, DGI 20 may be positioned over the interfaces between the multiple substrates.

As used in this specification and the claims, the singular forms “a,” “an,” and “the” refer to plural referents unless the context clearly dictates otherwise. For example, reference to “the first doped portion” in the singular includes a plurality of first doped portions, and reference to “the second doped portion” in the singular includes one or more second doped portions and equivalents known to those skilled in the art. Thus, in various embodiments, any reference to the singular includes a plurality, and any reference to more than one component can include the singular.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein.

It is, therefore, to be understood that the foregoing embodiments are presented by way of example only and that, within the scope of the appended claims and equivalents thereto, inventive embodiments may be practiced otherwise than as specifically described and claimed. Illustrative embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure. Disclosed embodiments, or portions thereof, may be combined in ways not listed above and/or not explicitly claimed. Thus, one or more features from variously disclosed examples and embodiments may be combined in various ways. For example, it is to be understood that the present disclosure contemplates that, to the extent possible, one or more features of any embodiment can be combined with one or more features of any other embodiment.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Although the above discussion discloses various exemplary embodiments of the invention, it should be apparent that those skilled in the art can make various modifications that will achieve some of the advantages of the invention without departing from the true scope of the invention.

What is claimed is:

1. A method of growing diamond, the method comprising:
providing an initial substrate having a growth surface;
positioning a first layer of diamond growth inhibitor over a first area of the growth surface;
growing diamond on the growth surface using chemical vapor deposition, wherein growing the diamond includes growing a lateral overgrowth region over the diamond growth inhibitor,
positioning a second layer of diamond growth inhibitor over a second area of the growth surface that is at least partially offset from the first area, after growing the lateral overgrowth region, wherein the second layer of diamond growth inhibitor is at a height that is greater than or equal to the lateral overgrowth region.

2. The method of claim 1, further comprising repeating the steps of positioning diamond growth inhibitor over an offset area of the growth surface and growing diamond on the growth surface using chemical vapor deposition until threading defect density is reduced by at least 50% relative to the initial substrate in a reduced defect area.

3. The method of claim 2, wherein the reduced defect area has a maximum dimension of at least 2 inches.

4. The method as defined by claim 1, further comprising:
growing diamond on the growth surface using chemical vapor deposition, wherein the grown diamond includes a second lateral overgrowth region over the diamond growth inhibitor.

5. The method as defined by claim 1, wherein the first layer of diamond growth inhibitor and the second layer of diamond growth inhibitor are formed from the same material.

6. The method as defined by claim 1, wherein the lateral overgrowth region and the second lateral overgrowth region are on different layers.

7. The method as defined by claim 1, further comprising:
positioning a third diamond growth inhibitor over a third area of the growth surface that is at least partially offset form the first area and the second area; and
growing diamond on the growth surface using chemical vapor deposition, wherein the grown diamond includes a third lateral overgrowth region over the diamond growth inhibitor.

8. The method as defined by claim 7, wherein the first area of the growth surface, the second area of the growth surface, and the third area of the growth surface do not overlap.

9. The method as defined by claim 1, further comprising:
repeating the steps of:
positioning diamond growth inhibitor over an area of the growth surface; and
growing diamond on the growth surface using chemical vapor deposition, wherein the grown diamond includes an additional overgrowth region over the diamond growth inhibitor,
until substantially all of the growth surface of the diamond is defect free.

10. The method as defined by claim 1, further comprising:
growing a large-area high-quality grown diamond region.

11. The method as defined by claim 10, further comprising: removing the large-area high-quality grown diamond region from the remainder of the grown diamond.

12. The method as defined by claim 1, wherein the substrate is a single-crystal diamond substrate.

13. The method as defined by claim 1, wherein growing diamond is heteroepitaxial.

14. The method as defined by claim 1, and the substrate is formed from a non-diamond material

15. The method as defined by claim 1, wherein the grown diamond is single crystal.

16. The method as defined by claim 1, wherein amorphous carbon deposits over the diamond growth inhibitor.

17. The method as defined by claim 1, wherein the diamond growth inhibitor is formed from gold.

18. The method as defined by claim 1, wherein the diamond growth inhibitor is formed from aluminum oxide.

19. The method as defined by claim 1, further comprising:
etching the growth surface to form etched regions, the diamond growth inhibitor functioning as a mask preventing or reducing the formation of etched regions beneath the diamond growth inhibitor;
depositing a first doped diamond portion using chemical vapor deposition;
removing the diamond growth inhibitor;
positioning the diamond growth inhibitor over a second area of the growth surface;
etching the growth surface to form second etched regions, the diamond growth inhibitor functioning as a mask preventing or reducing the formation of the second etched regions beneath the diamond growth inhibitor;
depositing a second doped diamond portion using chemical vapor deposition, the second doped diamond portion having a different doping concentration from the first doped diamond portion.

20. The method as defined by claim 1, wherein the doped diamond portion includes boron, nitrogen, silicon, and/or phosphorous as dopants.
